(19) United States
(12) Patent Application Publication
(10) Pub. No.: US 2009/0134528 A1
(43) Pub. Date: May 28, 2009

(54) SEMICONDUCTOR PACKAGE, ELECTRONIC DEVICE INCLUDING THE SEMICONDUCTOR PACKAGE, AND METHOD OF MANUFACTURING THE SEMICONDUCTOR PACKAGE

(75) Inventors: Teak-Hoon LEE, Gyeonggi-do (KR); Nam-Seog KIM, Gyeonggi-do (KR); Pyoung-Wan KIM, Gyeonggi-do (KR); Chul-Yong JANG, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: Samsung Electronics Co, Ltd., Gyeonggi-do (KR)

(21) Appl. No.: 12/253,734

(22) Filed: Oct. 17, 2008

(30) Foreign Application Priority Data
Nov. 28, 2007 (KR) 10-2007-0122168

(51) Int. Cl. H01L 23/52

(52) U.S. Cl. 257/777; 257/E23.141

(57) ABSTRACT

Provided are a semiconductor package, an electronic device including the semiconductor package and a method of manufacturing the semiconductor package. The semiconductor package includes semiconductor chips mounted on a carrier, a first insulating layer sealing the semiconductor chips, first via-holes which are formed in the first insulating layer and expose a portion of each of the semiconductor chips, a first conductive pattern which is filled in the first via-holes and electrically connected to each of the semiconductor chips, and an external terminal which is electrically connected to the first conductive pattern. The semiconductor package is manufactured by performing an encapsulating process and a via-hole process.

### CROSS-REFERENCE TO RELATED APPLICATIONS

This U.S. non-provisional patent application claims priority under 35 U.S.C. §119 to Korean Patent Application No. 10-2007-0122168, filed on Nov. 28, 2007, the entire contents of which are hereby incorporated by reference.

### BACKGROUND

The present inventive concept disclosed herein relates to a semiconductor device, and more particularly, to a semiconductor package, an electronic device including the semiconductor package and a method of manufacturing the semiconductor package.

Recently, as electronic devices have become smaller, semiconductor packages in the electronic devices have become correspondingly smaller, thinner and lighter. Traditionally, a semiconductor package includes one semiconductor chip. However, a multi-chip package (MCP), which includes multiple semiconductor chips having various functions, has been recently developed. In other words, a variety of semiconductor chips can be stacked in one multi-chip package. It is not uncommon for semiconductor chips having different functions to also have different sizes. Thus, there is a need to develop a semiconductor package that can integrate multiple semiconductor chips of various chip sizes.

### SUMMARY

Some exemplary embodiments provide a semiconductor package. The semiconductor package may include semiconductor chips mounted on a carrier, a first insulating layer sealing the semiconductor chips, first via-holes which are disposed in the first insulating layer and expose a portion of each of the semiconductor chips, a first conductive pattern which is filled in the first via-holes and electrically connected to the semiconductor chips, and an external terminal electrically connected to the first conductive pattern.

### BRIEF DESCRIPTION OF THE DRAWINGS

The accompanying figures are included to provide a further understanding of the present inventive concept, and are incorporated in and constitute a part of this specification. The drawings illustrate exemplary embodiments of the present inventive concept and, together with the description, serve to explain principles of the present inventive concept. In the figures:

FIGS. 1A to 1E are cross-sectional views illustrating a method of manufacturing a semiconductor package in accordance with a first embodiment of the present inventive concept.

FIG. 1F is a cross-sectional view illustrating a method of manufacturing a semiconductor package in accordance with a modified example of the first embodiment of the present inventive concept.

FIG. 1G is a cross-sectional view illustrating a method of manufacturing a semiconductor package in accordance with another modified example of the first embodiment of the present inventive concept.

FIGS. 2A to 2C are cross-sectional views illustrating a method of manufacturing a semiconductor package in accordance with a second embodiment of the present inventive concept.

FIGS. 3A to 3E are cross-sectional views illustrating a method of manufacturing a semiconductor package in accordance with a third embodiment of the present inventive concept.

FIG. 3F is a cross-sectional view illustrating a method of manufacturing a semiconductor package in accordance with a modified example of the third embodiment of the present inventive concept.

FIGS. 4A to 4C are cross-sectional views illustrating a method of manufacturing a semiconductor package in accordance with a fourth embodiment of the present inventive concept.

FIG. 5A is a top plan view depicting a semiconductor package in accordance with the first embodiment of the present inventive concept.

FIG. 5B is a top plan view depicting a semiconductor package in accordance with the third embodiment of the present inventive concept.

FIG. 6 is a perspective view depicting an example of an electronic device using a semiconductor package of any of the first through fourth embodiments of the present inventive concept.

### DETAILED DESCRIPTION OF THE EMBODIMENTS

The present inventive concept now will be described more fully hereinafter with reference to the accompanying drawings, in which embodiments of the inventive concept are shown. This inventive concept may, however, be embodied in many different forms and should not be construed as limited to the embodiments set forth herein. Rather, these embodiments are provided so that this disclosure will be thorough and complete, and will fully convey the scope of the inventive concept to those skilled in the art. In the drawings, the size and relative sizes of layers and regions may be exaggerated for clarity. Like numbers refer to like elements throughout.

### First Embodiment

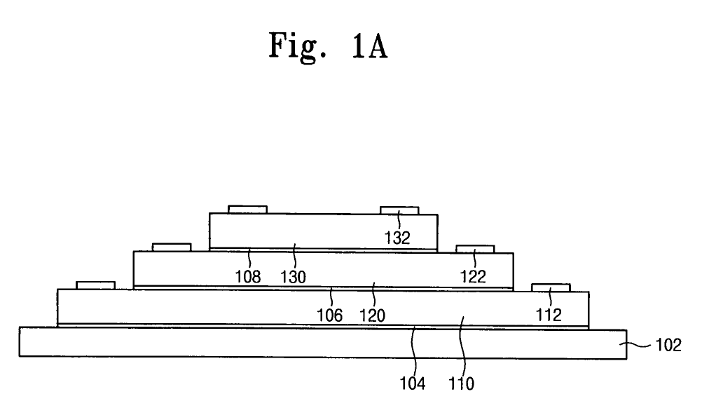

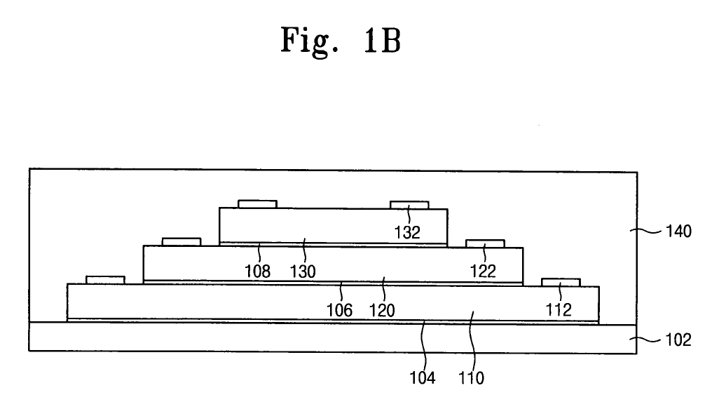

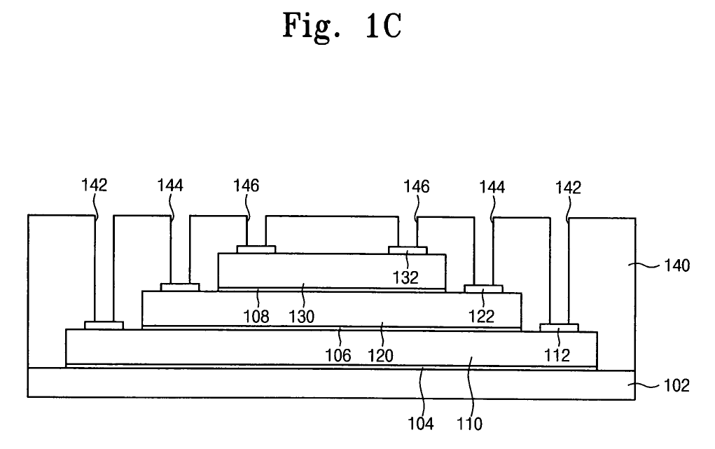

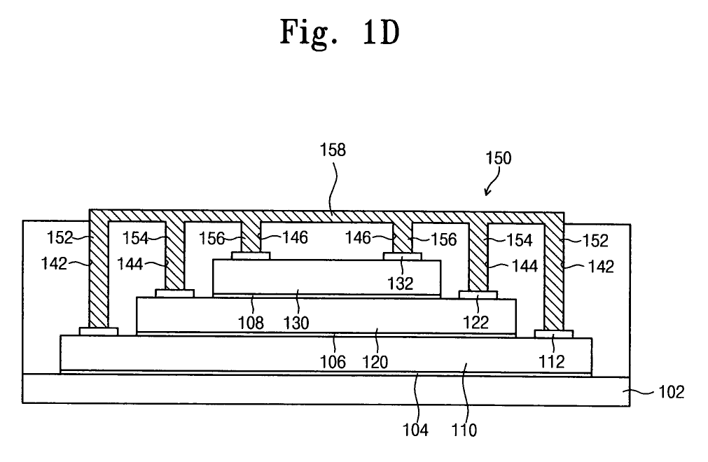

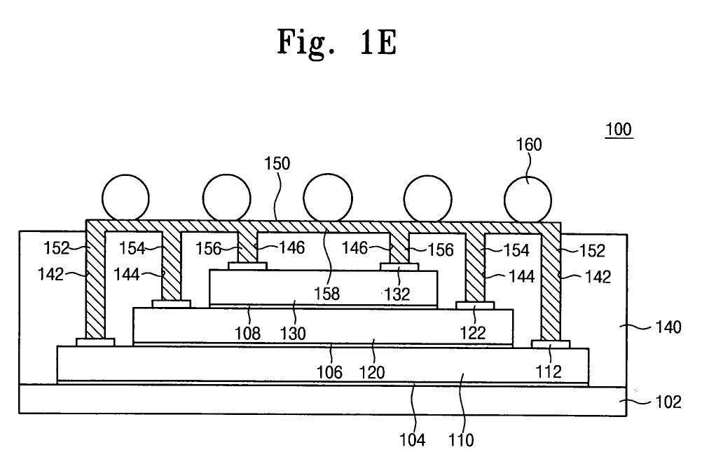

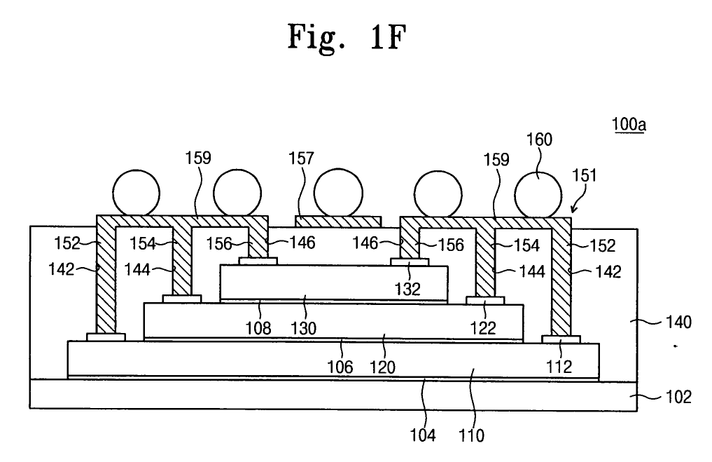

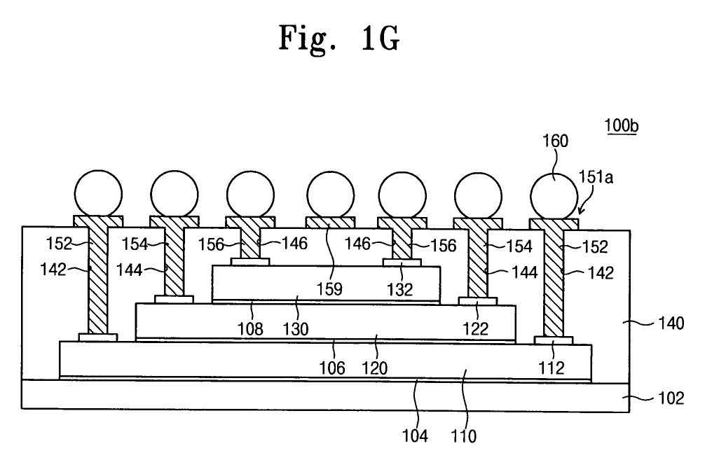

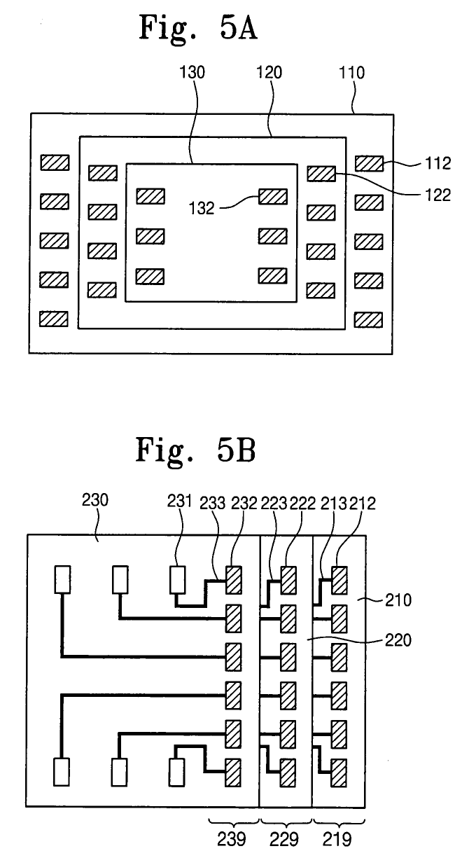

FIGS. 1A to 1E are cross-sectional views illustrating a method of manufacturing a semiconductor package in accordance with a first embodiment of the present inventive concept and FIG. 5A is a top plan view of the semiconductor package of FIG. 1A.

Referring to FIG. 1A, a plurality of semiconductor chips 110 and 120 are mounted on a carrier 102. For example, a first semiconductor chip 110 is mounted on the carrier 102 and a second semiconductor chip 120 is mounted on the first semiconductor chip 110. The carrier 102 may be a printed circuit board (PCB). As desired, a third semiconductor chip 130 may be further mounted on the second semiconductor chip 120. A first adhesive 104 may be interposed between the carrier 102 and the first semiconductor chip 110. Similarly, a second adhesive 106 may be interposed between the first semiconductor chip 110 and the second semiconductor chip 120, and a third adhesive 108 may be further interposed between the second semiconductor chip 120 and the third semiconductor chip 130.

Referring to FIG. 1A and FIG. 5A, a first pad 112 may be formed on an edge of the first semiconductor chip 110. Similarly, a second pad 122 may be formed on an edge of the second semiconductor chip 120 and a third pad 132 may be further formed on an edge of the third semiconductor chip 130. The first pad 112 may be formed of copper (Cu) with a predetermined height. Alternatively, a surface of the first pad 112 may be formed of some conductive material and surface-treated (e.g., plated) with copper. The second and third pads 122 and 132 may be prepared using the same or similar methods as those described above in connection with the first pad 112.

The size of each of the semiconductor chips 110, 120 and 130 may be different. For example, the first semiconductor chip 110 may have the largest size and the third semiconductor chip 130 may have the smallest size. The second semiconductor chip 120 may have an intermediate size which is smaller than the first semiconductor chip 110 and larger than the third semiconductor chip 130. Accordingly, the second semiconductor chip 120 may be stacked on the center of the first semiconductor chip 110 so as to expose the first pad 112. Similarly, the third semiconductor chip 130 may be stacked on the center of the second semiconductor chip 120 so as to expose the second pad 122. That is, the semiconductor chips 110, 120 and 130 may be stacked in the shape of a pyramid so as to expose both edges of each of the chips. In other words, the second semiconductor chip 120 can be centered on the first semiconductor chip 110 and the third semiconductor chip 130 can be centered on the second semiconductor chip. The semiconductor chips 110, 120 and 130 may be the same type of chips. For example, all of the chips may be DRAM memory devices. Alternatively, the semiconductor chips 110, 120 and 130 may be different types of chips. For example, the semiconductor chips 110, 120 and 130 may be a DRAM memory device, a SRAM memory device and a flash memory device, respectively. The semiconductor chips 110, 120 and 130 may be the same type of chips with different sizes. Alternatively, the semiconductor chips 110, 120 and 130 may be different types of chips with different sizes.

Referring to FIG. 1B, an encapsulation process, which forms an insulating layer 140 on the carrier 102 so as to seal up the semiconductor chips 110, 120 and 130, may be performed. The insulating layer 140 may be formed of epoxy molding compound (EMC). The encapsulation process may be performed using a compression mold or a transfer mold.

Referring to FIG. 1C, a first via-hole 142 exposing the first pad 112 may be formed by removing a portion of the insulating layer 140. Similarly, a second via-hole 144 exposing the second pad 122 and a third via-hole 146 exposing the third pad 132 may be formed. All the via-holes 142, 144 and 146 may be simultaneously formed using one via formation process. Alternatively, the via-holes 142, 144 and 146 may be formed separately using corresponding via formation processes. The first via-hole 142 may have the greatest depth and the third via-hole 146 may have the smallest depth relative to the other via holes. The second via-hole 144 may have an intermediate depth which is greater than the third via-hole 146 and smaller than the first via-hole 142.

The via-holes 142, 144 and 146 may be formed using a laser drilling method. Alternatively, the via-holes 142, 144 and 146 may be formed using an etching process such as a plasma etching. The laser drilling method does not need a mask formation and a photo process and the laser drilling method easily controls depths or widths of the via-holes 142, 144 and 146. Therefore, the laser drilling process may be suitably employed for formation of the via-holes 142, 144 and 146.

The pads 112, 122 and 132 may serve as a stop layer, preventing damage that can occur from the laser during a laser drilling process. For example, in the case that the via-holes 142, 144 and 146 having different depths are simultaneously formed, a laser may continue to be directed onto the second and third semiconductor chips 120 and 130 during the formation of the first via-hole 142 having the relatively greatest depth. In this case, the second and third pads 122 and 132 may act as laser stop layers, so that the second and third semiconductor chips 120 and 130 can be protected from laser damage.

Referring to FIG. 1D, a conductive pattern 150 electrically connected to the semiconductor chips 110, 120 and 130 may be formed using a conductive material. The conductive pattern 150 may be divided into a main pattern 158 and sub patterns 152, 154 and 156. The sub patterns 152, 154 and 156 may be filled in the via-holes 142, 144 and 146 so as to be disposed inside of the insulating layer 140. The main pattern 158 may be formed on the insulating layer 140 so as to be exposed outside the insulating layer 140 and electrically connected to the sub patterns 152, 154 and 156. The sub patterns 152, 154 and 156 may act as plugs which are electrically connected to the pads 112, 122 and 132. The main pattern 158 may act as a redistributed interconnection and/or a pad which is electrically connected to an external terminal. The main pattern 158 is depicted as an extended line in the drawings. However, the main pattern 158 may be an interconnection having a plurality of divergent branches.

The first via-hole 142 may be filled with a conductive material to form a first sub pattern 152 electrically connected to the first pad 112. Similarly, the second via-hole 144 may be filled with a conductive material to form a second sub pattern 154 electrically connected to the second pad 122 and the third via-hole 146 may be filled with a conductive material to form a third sub pattern 156 electrically connected to the third pad 132. The sub patterns 152, 154 and 156 may be simultaneously formed. The sub patterns 152, 154 and 156 may be formed by filling the via holes 142, 144, and 146 with a conductive material such as Cu or Ti/Cu and then using a chemical mechanical polishing process. The sub patterns 152, 154 and 156 may by formed by using one of an electroless Cu plating process, a Ti/Cu sputtering process and a Cu sputtering process.

The first sub pattern 152 may have the greatest relative height and the third sub pattern 156 may have the smallest relative height. The second sub pattern 154 may have an intermediate height which is greater than the third sub pattern 156 and smaller than the first sub pattern 152. After forming the sub patterns 152, 154 and 156, the main pattern 158 may be formed. The main pattern 158 may be formed using a patterning process after a conductive material is deposited on the insulating layer 140. Alternatively, the main pattern 158 may be formed using a plating process. According to some embodiments, the main pattern 158 and the sub patterns 152, 154 and 156 may be simultaneously formed using a plating process or the main pattern 158 and the sub patterns 152, 154 and 156 may be simultaneously formed using a patterning process after depositing a conductive material.

Referring to FIG. 1E, external terminals 160, such as solder balls, are attached to the conductive pattern 150 to complete the semiconductor package 100. The number of external terminals 160 may be more than one. In the drawing, a plurality of external terminals 160 are electrically connected to each other by the main terminal 158. However, as described above, the main pattern 158 may be an interconnection shape having a plurality of branches and each of the external terminals 160 may have an independent electrical function and may be electrically isolated from other external terminals 160.

In the semiconductor package 100 of the first embodiment, a plurality of semiconductor chips having various sizes may be stacked and the semiconductor chips 110, 120 and 130 may be electrically connected to the external terminals 160 through the conductive pattern 150. In the semiconductor package 100 of the first embodiment, since an encapsulation process and a via formation process are performed once, respectively, after the semiconductor chips 110, 120 and 130 having various sizes are mounted on the carrier 102, a manufacturing process for the semiconductor package 100 may be simplified.

FIGS. 1F and 1G are cross-sectional views illustrating a method of manufacturing a semiconductor package in accordance with modified examples of the first embodiment of the present inventive concept.

Referring to FIG. 1F, a conductive pattern 151 of a semiconductor package 100a according to a modification of the first embodiment of the present inventive concept may include sub patterns 152, 154 and 156, and main patterns 157 and 159 which are electrically connected to the sub patterns 152, 154 and 156. The main pattern 159, depicted as an extended line, may be an interconnection shape having a plurality of branches.

Referring to FIG. 1G, a conductive pattern 151a of a semiconductor package 100b according to another modification of the first embodiment of the present inventive concept may include sub patterns 152, 154 and 156, and main patterns 159 which are electrically connected to the sub patterns 152, 154 and 156. The main patterns 159 may have a divided shape which is individually electrically connected to each of the sub patterns 152, 154 and 156.

### Second Embodiment

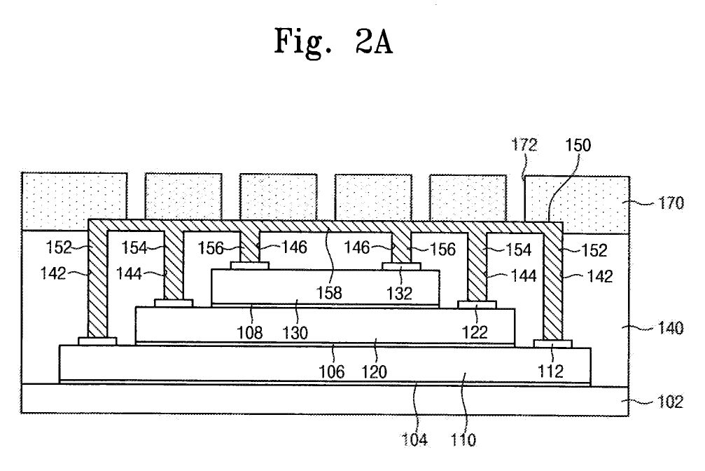

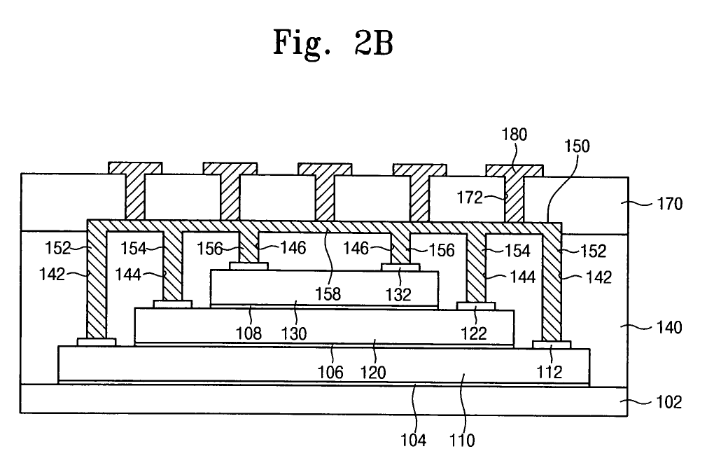

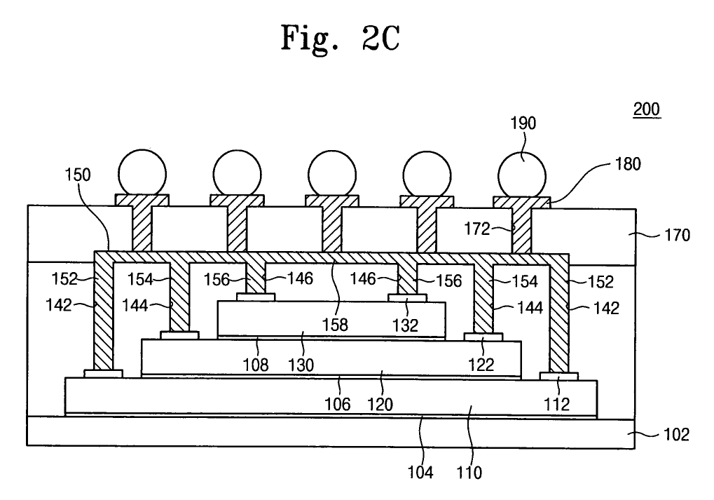

FIGS. 2A to 2C are cross-sectional views illustrating a method of manufacturing a semiconductor package in accordance with a second embodiment of the present inventive concept.

Referring to FIG. 2A, a plurality of semiconductor chips 110, 120 and 130 may be mounted on a carrier 102 in the shape of a pyramid by adhesives 104, 106 and 108, respectively. After forming an insulating layer 140, via-holes 142, 144 and 146 may be formed. A conductive pattern 150 including sub patterns 152, 154 and 156 and a main pattern 158 may be formed. After forming the conductive pattern 150, an insulating layer 170 may be additionally formed on the insulating layer 140 and via-holes 172 exposing the conductive pattern 150 may be formed. The insulating layer 170 may be composed of an epoxy molding compound. The via-holes 172 may be formed using a laser drilling process.

Referring to FIG. 2B, the via-holes 172 may be filled with a conductive material to further form a conductive pattern 180 electrically connected to the conductive pattern 150. The conductive pattern 180 may be electrically connected to an external terminal (190 of FIG. 2C).

Referring to FIG. 2C, external terminals 190, such as solder balls, may be attached to the conductive pattern 180. As a result, a semiconductor package 200 of the second embodiment may be manufactured. The semiconductor package 200 of the second embodiment may additionally have the insulating layer 170 and the conductive pattern 180 as compared with the semiconductor package 100 of the first embodiment. Thus, the semiconductor package 200 of the second embodiment may have added flexibility in the electrical connection to an external electronic device. In the semiconductor package 200 of the second embodiment, the conductive pattern 150 may be replaced by the conductive pattern 151 depicted in FIG. 1F or the conductive pattern 151a depicted in FIG. 1G.

### Third Embodiment

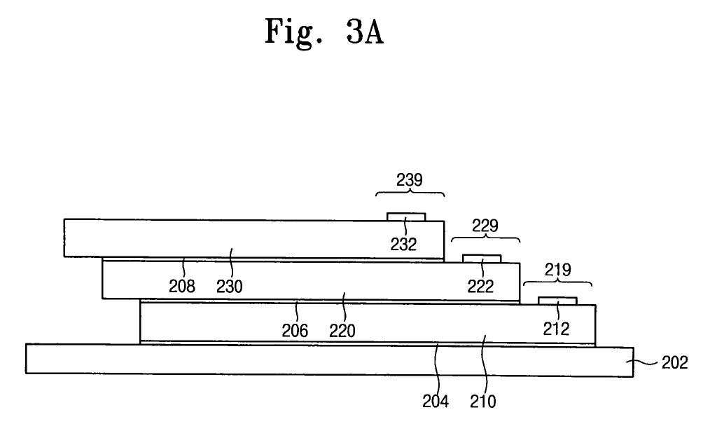

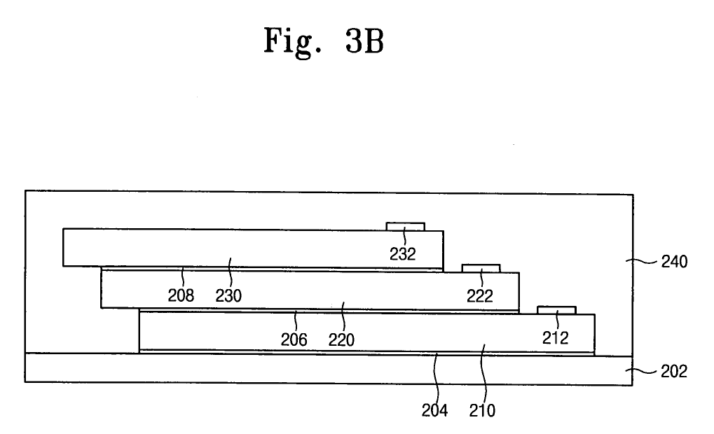

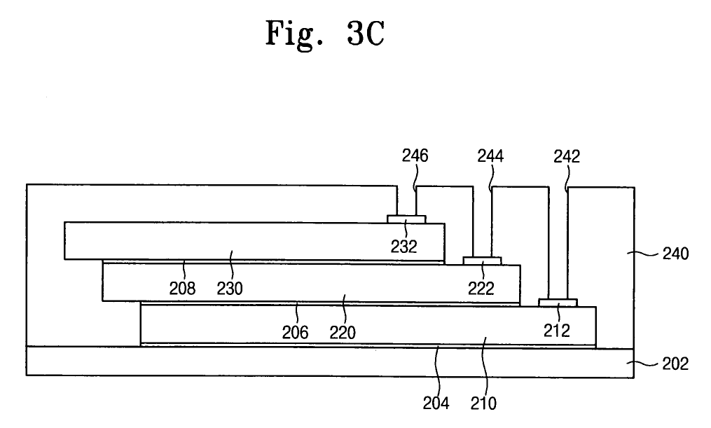

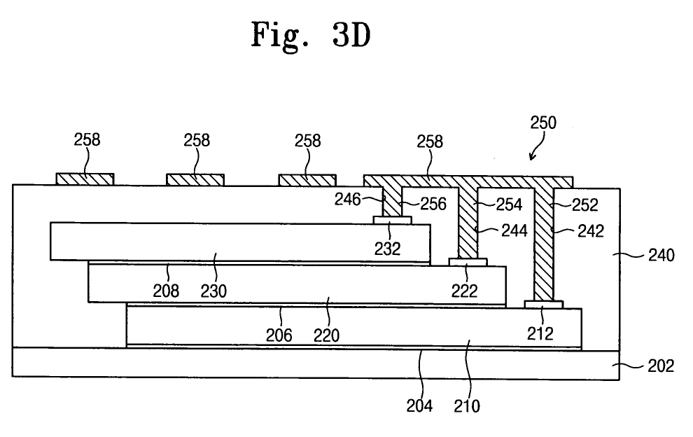

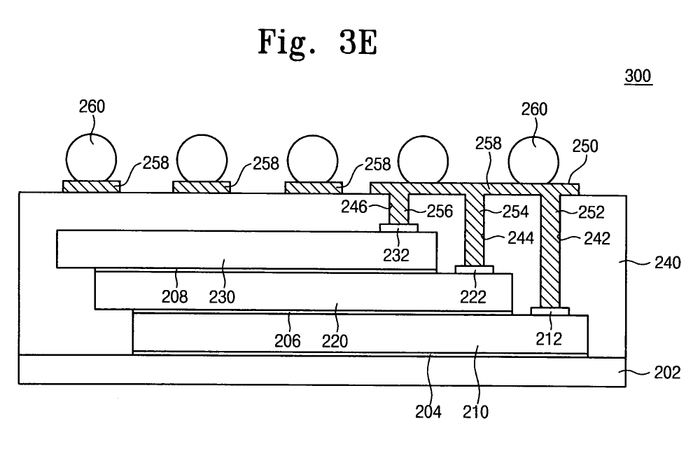

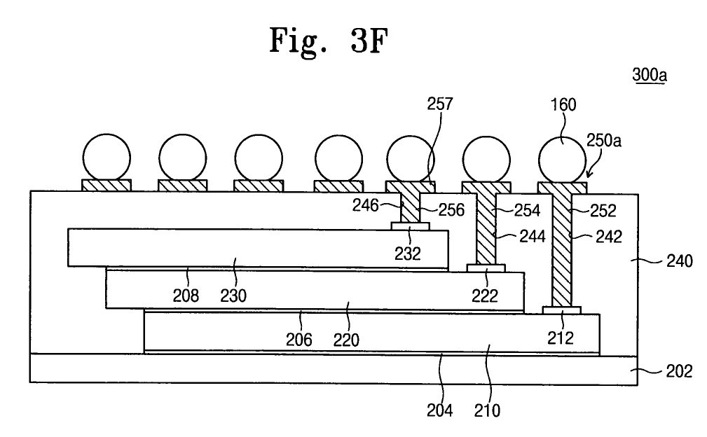

FIGS. 3A to 3E are cross-sectional views illustrating a method of manufacturing a semiconductor package in accordance with a third embodiment of the present inventive concept. FIG. 5B is a top plan view of the semiconductor package of FIG. 3A.

Referring to FIG. 3A, first and second semiconductor chips 210 and 220 may be sequentially mounted on a carrier 202. A third semiconductor chip 230 may be further mounted on the second semiconductor chip 220. A first adhesive 204 may be interposed between the carrier 202 and the first semiconductor chip 210. Similarly, a second adhesive 206 may be interposed between the first and second semiconductor chips 210 and 220, and a third adhesive 208 may be interposed between the second and third semiconductor chips 220 and 230.

Referring to FIG. 3A together with FIG. 5B, the sizes of the semiconductor chips 210, 220 and 230 may be substantially equal to each other. Thus, if the semiconductor chips 210, 220 and 230 are stacked in the shape of the first embodiment or pyramid fashion, pads of the semiconductor chips 210, 220 and 230 may not be exposed. For instance, because pads of the first semiconductor chip 210 are covered with the second semiconductor chip 220, the pads of the first semiconductor chip 20 may not be exposed. According to the third embodiment, redistributed pads 212, 222 and 232 may be formed on one side edge of each of the semiconductor chips 210, 220 and 230 and the redistributed pads 212, 222 and 232 may be exposed by stacking the semiconductor chips 210, 220 and 230 in a stair-step shape. Accordingly, one of the side edges of each of the first and second semiconductor chips 210 and 220 are exposed to allow electrical connections on the semiconductor chips.

For example, a first redistributed pad 212 may be formed on one side edge 219 of the first semiconductor chip 210. Likewise, a second redistributed pad 222 may be formed on one side edge 229 of the second semiconductor chip 220 and a third redistributed pad 232 may be formed on one side edge 239 of the third semiconductor chip 230. The third redistributed interconnection 232 may be electrically connected to an original pad 231 through a redistributed interconnection 233. The third redistributed pads 232 may be arranged on one side edge in a column and the original pads 231 may be arranged on top and bottom edges in a row. The first redistributed interconnection 212 may be electrically connected to an original pad through a redistributed interconnection 213. The second redistributed interconnection 222 may be electrically connected to an original pad through a redistributed interconnection 223.

The second semiconductor chip 220 may be mounted so as to be offset toward a side edge of the first semiconductor chip 210 so that the first redistributed pad 212 may be exposed. Similarly, the third semiconductor chip 230 may be mounted so as to be offset toward a side edge of the second semiconductor chip 220 so that the second redistributed pad 222 may be exposed. That is, the semiconductor chips 210, 220 and 230 may be stacked in a stair-step shape. The semiconductor chips 210, 220 and 230 may be the same type of chips. For example, all of the chips 210, 22 and 230 may be DRAM memory devices. Alternatively, the semiconductor chips 210, 220 and 230 may be different types of chips. For example, the semiconductor chips 110, 120 and 130 may be a DRAM memory device, an SRAM memory device and a flash memory device, respectively. The semiconductor chips 210, 220 and 230 may be the same type of chips with different sizes. Alternatively, the semiconductor chips 210, 220 and 230 may be different types of chips with different sizes.

Referring to FIG. 3B, an encapsulating process, which forms an insulating layer 240 of an epoxy molding compound surrounding the semiconductor chips 210, 220 and 230, may be performed on the carrier 202.

Referring to FIG. 3C, a portion of the insulating layer 240 may be removed to form a first via-hole 242 exposing the first redistributed pad 212. Similarly, a portion of the insulating layer 240 may be removed to form a second via-hole 244 exposing the second redistributed pad 222 and a portion of the insulating layer 240 may be removed to form a third via-hole 246 exposing the third redistributed pad 232. The via-holes 242, 244 and 246 may be simultaneously formed using one via formation process. Alternatively, the via-holes 242, 244 and 246 may be formed using separate via formation processes.

Referring to FIG. 3D, a conductive pattern 250 electrically connected to the semiconductor chips 210, 220 and 230 may be formed using a conductive material. The conductive pattern 250 may be divided into sub patterns 252, 254 and 256, and a main pattern 258. The sub patterns 252, 254 and 256 may be filled in the via-holes 242, 244 and 246 and disposed inside of the insulating layer 240. The main pattern 258 may be formed on the insulating layer 240 so as to be exposed outside of the insulating layer 240 and electrically connected to the sub patterns 252, 254 and 256. The sub patterns 252, 254 and 256 may function as plugs and the main pattern 258 may function as a redistributed interconnection and/or a pad. The main pattern 258 may be an interconnection shape having a plurality of divergent branches.

Referring to FIG. 3E, external terminals 260, such as solder balls, may be attached to the conductive pattern 250. Thereby, a semiconductor package 300 of the third embodiment may be manufactured in which a plurality of semiconductor chips 210, 220 and 230, including the redistributed interconnections 212, 222 and 232, of the same size are stacked in a stair-step shape.

FIG. 3F is a cross-sectional view illustrating a method of manufacturing a semiconductor package in accordance with a modification of the third embodiment of the present inventive concept.

Referring to FIG. 3F, a conductive pattern 250a of a semiconductor package 300a according to a modified example of the third embodiment of the present inventive concept may include sub patterns 252, 254 and 256, and main patterns 257 electrically connected to the sub patterns 252, 254 and 256. The main patterns 257 may be separated from each other and electrically connected to each of the sub patterns 252, 254 and 256.

### Fourth Embodiment

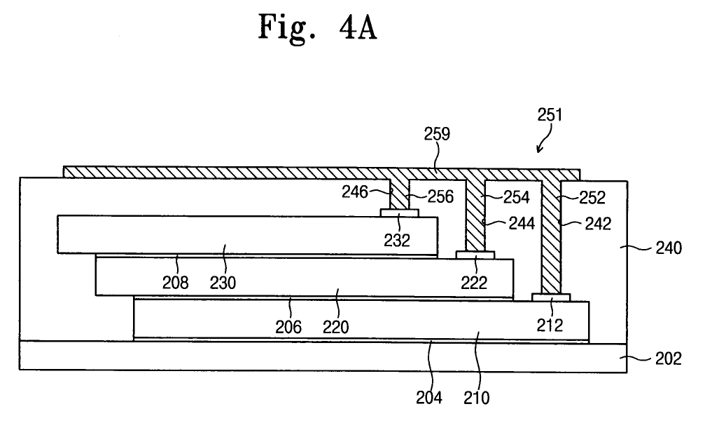

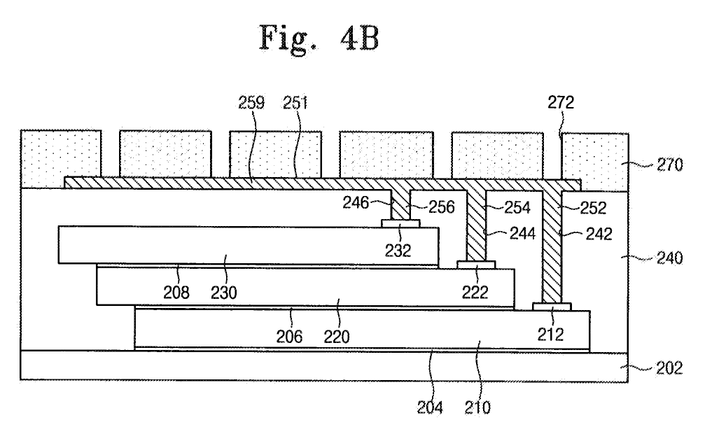

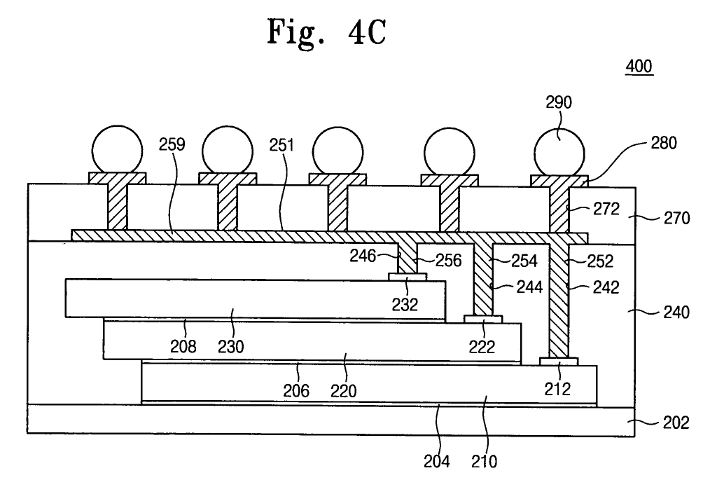

FIGS. 4A to 4C are cross-sectional views illustrating a method of manufacturing a semiconductor package in accordance with a fourth embodiment of the present inventive concept.

Referring to FIG. 4A, a plurality of semiconductor chips 210, 220 and 230 may be mounted on a carrier 202 in a stair-step shape using adhesives 204, 206 and 208. After forming an insulating layer 240, via-holes 242, 244 and 246 may be formed. After the via-holes 242, 244 and 246 are formed, a conductive pattern 251 electrically connected to the semiconductor chips 210, 220 and 230 using a conductive material may be formed. The conductive pattern 251 may be divided into sub patterns 252, 254 and 256 which are filled in the via-holes 242, 244 and 246 and a main pattern 259 which is disposed on the insulating layer 240 and electrically connected to the sub patterns 252, 254 and 256. The sub patterns 252, 254 and 256 may function as plugs and the main pattern 259 may function as a redistributed interconnection.

Referring to FIG. 4B, after forming the conductive pattern 251, an insulating layer 270 may be formed on the insulating layer 240 and via-holes 272 exposing the conductive pattern 251 may be further formed. The insulating layer 270 may be formed of an epoxy molding compound. The via-holes 272 may be formed using a laser drilling process.

Referring to FIG. 4C, the via-holes 272 may be filled to form a conductive pattern 280 electrically connected to the conductive pattern 251. The conductive pattern 280 may function as a pad and an external terminal, such as a solder ball, may be attached to the conductive pattern 280. Thus, a semiconductor package 400 of the fourth embodiment may be manufactured. Because the semiconductor package 400 of the fourth embodiment additionally includes the insulating layer 270 and the conductive pattern 280 as compared with a structure of the semiconductor package of the third embodiment, the semiconductor package 400 of the fourth embodiment may have added flexibility for electrical connection to an external electronic device. In the semiconductor package 400 of the fourth embodiment, the conductive pattern 251 may be replaced by the conductive pattern 250 of FIG. 3E or the conductive pattern 250a of FIG. 3F.

### Electronic Device Embodiment

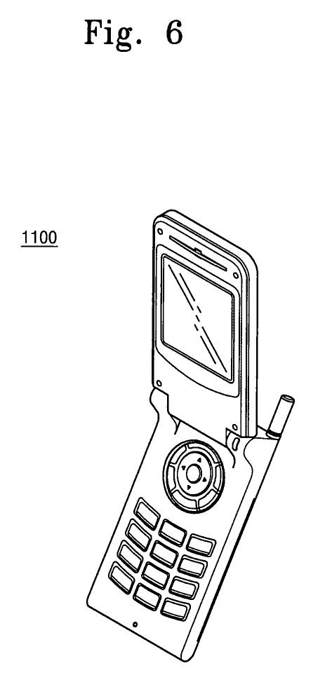

FIG. 6 is a perspective view depicting an example of an electronic device using a semiconductor package of any of the first through fourth embodiments of the present inventive concept.

Referring to FIG. 6, at least one of the semiconductor packages 100, 200, 300 and 400 according to some embodiments of the present inventive concept may be used in an electronic device such as a cellular phone 1100. Because the cellular phone 1100 includes a plurality of semiconductor chips of the same size or a different size, it can serve as a camera, an MP3 player, an electronic settlement system, etc.

The electronic device may include, among other things, a notebook computer, a desktop computer, a camcorder, a game machine, a portable multimedia player, an MP3 player, a liquid crystal display, a plasma display and a memory card.

Some exemplary embodiments of the present inventive concept provide a semiconductor package. The semiconductor package may include semiconductor chips mounted on a carrier, a first insulating layer sealing the semiconductor chips, first via-holes which are disposed in the first insulating layer and expose a portion of each of the semiconductor chips, a first conductive pattern which is filled in the first via-holes and electrically connected to the semiconductor chips, and an external terminal electrically connected to the first conductive pattern.

Some exemplary embodiments provide a semiconductor package. The semiconductor package may include an insulating layer formed on a carrier, semiconductor chips which are mounted on the carrier so that the semiconductor chips are sealed by the insulating layer and are stacked so that edges of the semiconductor chips are exposed, a conductive pattern which includes sub patterns electrically connected to the edges of the semiconductor chips and a main pattern electrically connected to the sub patterns, and an external terminal electrically connected to the semiconductor chips by the conductive pattern.

Some exemplary embodiments provide a method of manufacturing a semiconductor package. The method may include mounting semiconductor chips on a carrier, forming an insulating layer sealing the semiconductor chips, forming via-holes exposing a portion of the semiconductor chips in the insulating layer, forming a conductive pattern electrically connected to the semiconductor chips by filling the via-holes with a conductor, and attaching an external terminal to the conductive pattern.

The above-disclosed subject matter is to be considered illustrative, and not restrictive, and the appended claims are intended to cover all such modifications, enhancements, and other embodiments, which fall within the true spirit and scope of the present inventive concept. Thus, to the maximum extent allowed by law, the scope of the present inventive concept is to be determined by the broadest permissible interpretation of the following claims and their equivalents, and shall not be restricted or limited by the foregoing detailed description.

What is claimed is:

1. A semiconductor package, comprising:
a plurality of semiconductor chips mounted on a carrier;
a first insulating layer disposed on the semiconductor chips;
a plurality of first via-holes disposed in the first insulating layer and exposing a portion of each of the semiconductor chips;
a first conductive pattern disposed in the first via-holes and electrically connected to the semiconductor chips; and
an external terminal electrically connected to the first conductive pattern.

2. The semiconductor package of claim 1, wherein the semiconductor chips have different sizes.

3. The semiconductor package of claim 2, wherein the semiconductor chips comprise:
a first semiconductor chip mounted on the carrier and including a plurality of first pads disposed along at least two edges of the first semiconductor chip; and
a second semiconductor chip smaller than the first semiconductor chip and including a plurality of second pads disposed along at least two edges of the second semiconductor chip, the second semiconductor chip being disposed on the first semiconductor chip such that the first pads are not covered by the second semiconductor chip.

4. The semiconductor package of claim 1, wherein the semiconductor chips have substantially the same size.

5. The semiconductor package of claim 1, wherein the semiconductor chips comprise:
a first semiconductor chip disposed on the carrier and including a first pad on one side edge of the first semiconductor chip; and
a second semiconductor chip stacked on and offset to one side of the first semiconductor chip such that the first pad is not covered by the second semiconductor chip, the second semiconductor chip including a second pad disposed on a side edge of the second semiconductor chip.

6. The semiconductor package of claim 5, wherein at least one of the first and second pads is a redistributed pad.

7. The semiconductor package of claim 1, wherein the first conductive pattern comprises:
a first pattern disposed in the first via-holes and electrically connected to the semiconductor chips; and
a second pattern disposed on the first insulating layer and electrically connected to the first pattern, wherein the external terminal is attached to the second pattern.

8. The semiconductor package of claim 1, further comprising:
a second insulating layer disposed on the first insulating layer;
a second via-hole in the second insulating layer, the second via-hole exposing a portion of the first conductive pattern; and
a second conductive pattern disposed in the second via-hole and electrically connected to the first conductive pattern, wherein the external terminal is attached to the second conductive pattern.

9. A semiconductor package, comprising:
an insulating layer disposed on a carrier;
a plurality of semiconductor chips stacked on the carrier such that the semiconductor chips are covered by the insulating layer and edges of lower semiconductor chips are exposed by higher semiconductor chips;
a conductive pattern including sub patterns electrically connected to exposed edges of the semiconductor chips and a main pattern electrically connected to the sub patterns; and
an external terminal electrically connected to the semiconductor chips by the conductive pattern.

10. The semiconductor package of claim 9, wherein each of the semiconductor chips includes a plurality of pads disposed on at least two edges of the semiconductor chip and electrically connected to the sub patterns, and wherein the semiconductor chips have different sizes such that the semiconductor chips are stacked in a pyramid shape.

11. The semiconductor package of claim 9, wherein each of the semiconductor chips includes redistributed pads disposed on one side edge of the semiconductor chip and electrically connected to the sub patterns, and wherein the semiconductor chips have substantially the same size and are stacked in a stair-step shape.

12. The semiconductor package of claim 9, wherein the sub patterns are disposed in the insulating layer, and wherein the main pattern is exposed outside of the insulating layer so as to contact the external terminal.

13. The semiconductor package of claim 9, wherein the insulating layer comprises a first insulating layer covering the semiconductor chips and a second insulating layer disposed on the first insulating layer, and wherein the conductive pattern comprises a first conductive pattern disposed on the first insulating layer and electrically connected to the semiconductor chips and a second conductive pattern disposed on the second insulating layer and electrically connected to the first conductive pattern.

14. The semiconductor package of claim 13, wherein the first conductive pattern comprises sub patterns which are disposed in the first insulating layer and electrically connected to the semiconductor chips and a main pattern which is disposed on the first insulating layer and electrically connected to the sub patterns, and wherein the second conductive pattern is electrically connected to the main pattern and the external terminal is in direct contact with the second conductive pattern.

15. A semiconductor package, comprising:
a first semiconductor chip disposed on a carrier, the first semiconductor chip including first pads disposed on the first semiconductor chip;
a second semiconductor chip disposed on the first semiconductor chip, the second semiconductor chip including second pads disposed on the second semiconductor chip, wherein the first pads are exposed by the second semiconductor chip;
a first insulating layer disposed on the carrier and the first and second semiconductor chips;
a plurality of first via-holes disposed in the first insulating layer, the first via-holes exposing the first and second pads;
a first conductive pattern disposed in the via-holes and on the first insulating layer, wherein at least a portion of the first conductive pattern extends across a surface of the first insulating layer; and
a plurality of external terminals electrically connected to the first and second pads through the first conductive pattern.

16. The semiconductor package of claim 15, further comprising a third semiconductor chip disposed on the second semiconductor chip, the third semiconductor chip exposing the second pads, wherein third pads on the third semiconductor chip are electrically connected to the external terminals through the first conductive pattern.

17. The semiconductor package of claim 15, further comprising:
a second insulating layer disposed on the first insulating layer and the first conductive pattern;
a plurality of second via-holes disposed in the second insulating layer, the second via holes exposing the first conductive pattern; and
a second conductive pattern disposed in the second via holes and on the second insulating layer, wherein the external terminals are disposed on the second conductive pattern and wherein the external terminals are electrically connected to the first and second pads through the first conductive pattern and the second conductive pattern.

18. The semiconductor package of claim 15, wherein the second semiconductor chip is smaller than the first semiconductor chip and wherein the second semiconductor chip is centered on the first semiconductor chip.

19. The semiconductor package of claim 15, wherein the first and second semiconductor chips have substantially the same size and wherein the second semiconductor chip is offset on the first semiconductor chip.

20. The semiconductor package of claim 19, wherein the first semiconductor chip further includes a plurality of original pads and a plurality of redistributed interconnections electrically connecting the original pads to the first pads.
